(19) United States
(12) Patent Application Publication
(10) Pub. No.: US 2024/0416529 A1
(43) Pub. Date: Dec. 19, 2024

(54) ROBOT BLADE

(71) Applicant: Samsung Electronics Co., Ltd., Suwon-si (KR)

(72) Inventors: Kyunghoon Joo, Suwon-si (KR); Sunghyup Kim, Suwon-si (KR); Kiho Lee, Suwon-si (KR); Sanghoon Lee, Suwon-si (KR)

(21) Appl. No.: 18/522,855

(22) Filed: Nov. 29, 2023

(30) Foreign Application Priority Data
Jun. 14, 2023 (KR) 10-2023-0075928

(51) Int. Cl. B25J 15/00; H01L 21/687

(52) U.S. Cl. CPC B25J 15/0019; H01L 21/68707

(57) ABSTRACT

A robot blade may include a blade body and a frequency variator. The blade body may include a frequency variation groove. The frequency variator may be detachably arranged in the frequency variation groove to vary a frequency of the blade body. Thus, the robot blade may have a changed shape by removing at least one frequency variation block included in the frequency variator. Therefore, the robot blade having the changed shape may have a frequency different from a frequency of a part in semiconductor fabrication equipment to prevent a resonance. As a result, a vibration of the robot blade may be suppressed to prevent damage to a semiconductor substrate.

### CROSS-REFERENCE TO RELATED APPLICATION

This application claims priority under 35 USC § 119 to Korean Patent Application No. 10-2023-0075928, filed on Jun. 14, 2023 in the Korean Intellectual Property Office (KIPO), the contents of which are herein incorporated by reference in their entirety.

### BACKGROUND

Example embodiments relate to a robot blade. More particularly, example embodiments relate to a robot blade configured to transfer a semiconductor substrate.

Generally, a robot blade may transfer a semiconductor substrate in semiconductor fabrication equipment. The robot blade may have a cantilever shape. Thus, the robot blade may be vulnerable to a vibration.

According to related arts, when a frequency of the robot blade may be coincided with a frequency of a part in the semiconductor fabrication equipment, a resonance may be generated. The resonance may amplify the vibration of the robot blade so that a damage such as a scratch may be generated at the semiconductor substrate on the robot blade.

### SUMMARY

Example embodiments provide a robot blade that may be capable of preventing a resonance.

According to example embodiments, there may be provided a robot blade. The robot blade may include a blade body and a frequency variator. The blade body may include a frequency variation groove. The frequency variator may be configured to be detachably arranged in the frequency variation groove to vary a frequency of the blade body.

According to example embodiments, there may be provided a robot blade. The robot blade may include a blade body and a plurality of frequency variation blocks. The blade body may include a rectangular frequency variation groove at an upper surface of the blade body. The frequency variation blocks may be configured to be detachably arranged in the frequency variation groove to vary a frequency of the blade body.

According to example embodiments, there may be provided a robot blade. The robot blade may include a blade body and a plurality of frequency variation blocks. The blade body may include a rectangular frequency variation groove at an upper surface of the blade body. The frequency variation blocks may be configured to be detachably arranged in the frequency variation groove to vary a frequency of the blade body. The frequency variation blocks may be configured to be arranged in a tessellation to collectively have an area substantially equal to an area of the frequency variation groove. The frequency variation blocks may include a central block, a plurality of side blocks and a pair of edge blocks. The central block may be configured to be arranged in a central portion of the frequency variation groove. The side blocks may have first side surfaces configured to contact first side surfaces of the central block, respectively. The pair of edge blocks may be configured to contact second side surfaces of the central block, respectively, and second side surfaces of the side blocks, respectively. The second side surfaces of the central block may be substantially perpendicular to the first side surfaces of the central block. The second side surfaces of the side blocks may be substantially perpendicular to the first side surfaces of the side blocks.

According to example embodiments, when the frequency of the blade body is coincided with a frequency of a part in semiconductor fabrication equipment, at least one of the frequency variation blocks may be removed from the frequency variation groove. Thus, the robot blade may have a changed shape by removing the at least one of the frequency variation blocks. Therefore, the robot blade having the changed shape may have a frequency different from the frequency of the part to prevent a resonance. As a result, a vibration of the robot blade may be suppressed to prevent damage to a semiconductor substrate.

### BRIEF DESCRIPTION OF THE DRAWINGS

Example embodiments will be more clearly understood from the following detailed description taken in conjunction with the accompanying drawings. FIGS. 1 to 15 represent non-limiting, example embodiments as described herein.

FIG. 1 is a plan view illustrating a robot blade in accordance with example embodiments;

FIG. 2 is a plan view illustrating a blade body of the robot blade in FIG. 1;

FIG. 3 is a plan view illustrating a frequency variator of the robot blade in FIG. 1;

FIG. 4 is a plan view illustrating the robot blade in FIG. 1 having a changed frequency;

FIG. 5 is a plan view illustrating a robot blade in accordance with example embodiments;

FIG. 6 is a plan view illustrating a blade body of the robot blade in FIG. 5;

FIG. 7 is a plan view illustrating a frequency variator of the robot blade in FIG. 5;

FIG. 8 is a plan view illustrating a robot blade in accordance with example embodiments;

FIG. 9 is a plan view illustrating a blade body of the robot blade in FIG. 8;

FIG. 10 is a plan view illustrating a frequency variator of the robot blade in FIG. 8;

FIG. 11 is a plan view illustrating a robot blade in accordance with example embodiments;

FIG. 12 is a plan view illustrating a robot blade in accordance with example embodiments;

FIG. 13 is a plan view illustrating a robot blade in accordance with example embodiments;

FIG. 14 is a plan view illustrating a blade body of the robot blade in FIG. 13; and

FIG. 15 is a plan view illustrating a frequency variator of the robot blade in FIG. 13.

### DETAILED DESCRIPTION

Hereinafter, example embodiments will be explained in detail with reference to the accompanying drawings.

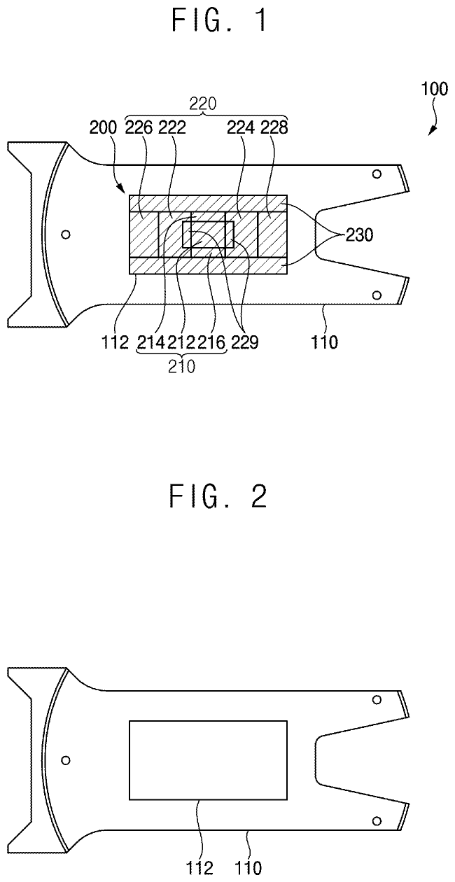

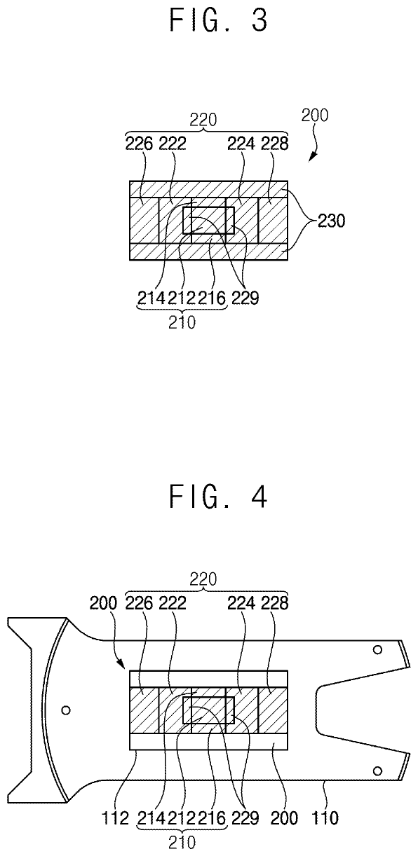

FIG. 1 is a plan view illustrating a robot blade in accordance with example embodiments, FIG. 2 is a plan view illustrating a blade body of the robot blade in FIG. 1 and FIG. 3 is a plan view illustrating a frequency variator of the robot blade in FIG. 1.

Referring to FIG. 1, a robot blade 100 may transfer a semiconductor substrate in semiconductor fabrication equipment. Further, the robot blade 100 may perform a scanning operation for detecting the semiconductor substrate. The robot blade 100 may have a cantilever shape so that the robot blade 100 may be vulnerable to a vibration. Particularly, a resonance, which may be generated when a frequency of the robot blade 100 may be coincided with a frequency of a part in the semiconductor fabrication equipment, may amplify the vibration of the robot blade 100. The robot blade 100 of example embodiments may have a structure for avoiding the resonance.

Referring to FIGS. 1 to 3, the robot blade 100 of example embodiments may include a blade body 110 and a frequency variator 200.

The blade body 110 may be horizontally arranged in the semiconductor fabrication equipment. Thus, the blade body 110 may have an upper surface and a lower surface. The semiconductor substrate may be placed on the upper surface of the blade body 110. The blade body 110 may have the cantilever shape.

The blade body 110 may include a frequency variation groove 112. In example embodiments, the frequency variation groove 112 may be formed at the upper surface of the blade body 110, but is not limited thereto.

In example embodiments, the frequency variation groove 112 may be positioned in a central portion of the upper surface of the blade body 110. Further, the frequency variation groove 112 may have a rectangular shape, but is not limited thereto. The frequency variation groove 112 may have a uniform depth, but is not limited thereto.

The frequency variator 200 may be detachably arranged in the frequency variation groove 112. When the frequency variation groove 112 is fully filled with the frequency variator 200, this shape may be substantially the same as a shape of a conventional robot blade without the frequency variation groove 112. Thus, the robot blade 100 of example embodiments may have a shape different from the shape of the conventional robot blade by partially or fully removing the frequency variator 200 from the frequency variation groove 112. As a result, the robot blade 100 of example embodiments may selectively have a frequency different from a frequency of the conventional robot blade by changing the shape of the robot blade 100.

In example embodiments, the frequency variator 200 may include a plurality of frequency variation blocks. The frequency variation blocks may be detachably arranged in the frequency variation groove 112. Thus, the shape of the robot blade 100 may be changed by removing at least one of the frequency variation blocks from the frequency variation groove 112. That is, remaining frequency variation blocks may be selectively arranged in the frequency variation groove 112 to change the shape of the robot blade 100. For example, the frequency variation blocks may collectively have an area substantially equal to an area of the frequency variation groove 112.

Further, the frequency variation blocks may be arranged in a puzzle. In other words, the frequency variation blocks may be arranged in a tessellation. As used herein “arranged in a tessellation” (or similar language) may refer to covering a surface (e.g., the frequency variation groove 112) using one or more geometric shapes (e.g., the frequency variation blocks) with no overlaps and no gaps in a non-repeating or a repeating manner. The frequency variation blocks may make contact with each other. Thus, at least one selected frequency variation block among the frequency variation blocks may be readily removed from the frequency variation groove 112. In contrast, non-selected frequency variation blocks may be maintained at original positions in the frequency variation groove 112.

In example embodiments, the frequency variation blocks may include a central block 210, a plurality of side blocks 220 and a pair of edge blocks 230. The central block 210, the side blocks 220 and the edge blocks 230 may have rectangular shapes, but are not limited thereto.

The central block 210 may be positioned at a central portion of the frequency variation groove 112. Because the central block 210 may have the rectangular shape, the central block 210 may have first side surfaces and second side surfaces substantially perpendicular to the first side surfaces. For example, the first side surfaces of the central block 210 may oppose each other, and the second side surfaces of the central block 210 may oppose each other.

The side blocks 220 may be sequentially arranged on the first side surfaces of the central block 210. As mentioned above, the frequency variation blocks may be arranged in the puzzle (e.g., arranged in the tessellation), inner side surfaces of inner side blocks 222 and 224 among the side blocks 220 may make contact with the first side surfaces of the central block 210, respectively. Inner side surfaces of outer side blocks 226 and 228 among the side blocks 220 may make contact with outer side surfaces of the inner side blocks 222 and 224, respectively. Each of the side blocks 220 may have an area substantially the same as an area of the central block 210, but is not limited thereto. For example, each of the inner side blocks 222 and 224 and each of the outer side blocks 226 and 228 may have an area that is substantially equal to an area of the central block 210, but is not limited thereto. Because each of the side blocks 220 may have the rectangular shape, the inner side surface and the outer side surface of each of the side blocks 220 may correspond to first side surfaces. Thus, each of the side blocks 220 may have second side surfaces substantially perpendicular to the first side surfaces of the side block 220. For example, the first side surfaces of each of the side blocks 220 may oppose each other, and the second side surfaces of each of the side blocks 220 may oppose each other.

The edge blocks 230 may make contact with the second side surfaces of the central block 210, respectively, and the second side surfaces of the side blocks 220, respectively. Thus, each of the edge blocks 230 may have a long rectangular shape on a plane, but is not limited thereto.

Additionally, the central block 210 may include a first central block 212 and a plurality of second central blocks 214 and 216. The first central block 212 may be arranged at the central portion of the frequency variation groove 112. The second central blocks 214 and 216 may be arranged between the second side surfaces of the first central block 212 and the edge blocks 230, respectively. For example, the second side surfaces of the first central block 212 may oppose each other.

Further, each of the side blocks 220 may include auxiliary side blocks 229. For example, the inner side blocks 222 and 224 may include auxiliary side blocks 229. Each of the inner side blocks 222 and 224 may include an auxiliary side block 229. The auxiliary side blocks 229 may make contact with the first side surfaces of the first central block 212, respectively. For example, the first side surfaces of the first central block 212 may oppose each other. The first side surfaces of the first central block 212 may be substantially perpendicular to the second side surfaces of the first central block 212.

The frequency variation blocks may have various other shapes and are not limited within the above-mentioned shape. For example, the frequency variation blocks may have a triangular shape, a circular shape, etc. Further, the puzzle structure (e.g., the tessellation structure) of the frequency variation blocks may have various other shapes.

FIG. 4 is a plan view illustrating the robot blade in FIG. 1 having a changed frequency.

Referring to FIGS. 1 to 4, in the semiconductor fabrication equipment, a frequency of the robot blade 100 of example embodiments with the frequency variation blocks in the frequency variation groove 112 may be measured. When the frequency of the robot blade 100 is different from a frequency of a part, a resonance may not be generated at the robot blade 100.

In contrast, when the frequency of the robot blade 100 is coincided with the frequency of the part, the resonance may be generated at the robot blade 100. In this case, as shown in FIG. 4, at least one of the frequency variation blocks may be removed from the frequency variation groove 112. In FIG. 4, the edge blocks 230 may be removed from the frequency variation groove 112, but example embodiments are not limited thereto. A frequency of the robot blade 100 without the edge blocks 230 may be measured. When the measured frequency of the robot blade 100 is different from the frequency of the part, the resonance may not be generated at the robot blade 100.

While the frequency of the robot blade 100 without the edge blocks 230 may be different from the frequency of the part, when the difference between the frequencies is not enough to avoid a resonance at the robot blade 100, at least one of the frequency variation blocks may be additionally removed from the frequency variation groove 112. The removal of the frequency variation blocks may be performed until the frequency of the robot blade 100 is such to avoid the resonance.

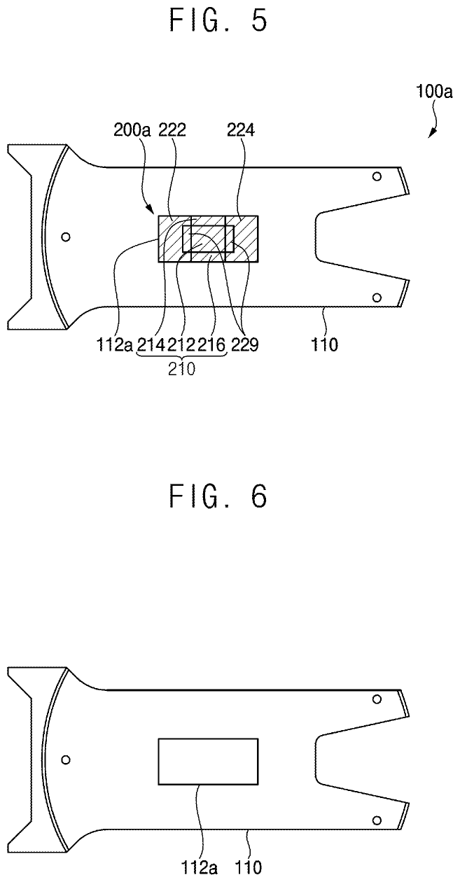

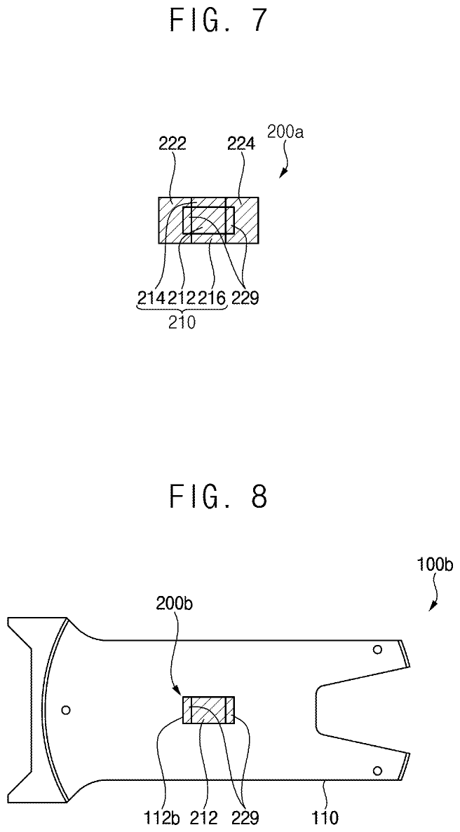

FIG. 5 is a plan view illustrating a robot blade in accordance with example embodiments, FIG. 6 is a plan view illustrating a blade body of the robot blade in FIG. 5 and FIG. 7 is a plan view illustrating a frequency variator of the robot blade in FIG. 5.

A robot blade 100a of example embodiments may include elements substantially the same as those of the robot blade 100 in FIG. 1 except for sizes of a frequency variation groove and a frequency variator. Thus, the same reference numerals may refer to the same elements and any further descriptions with respect to the same elements may be omitted herein for brevity.

Referring to FIGS. 5 to 7, a frequency variation groove 112a may be arranged at the central portion of the blade body 110. In example embodiments, the frequency variation groove 112a may have an area smaller than the area of the frequency variation groove 112 in FIG. 1. Thus, a frequency variator 200a selectively arranged in the frequency variation groove 112a may also have an area smaller than the area of the frequency variator 200 in FIG. 1.

For example, the frequency variator 200a may include only the central block 210 and the inner side blocks 222 and 224. That is, the frequency variator 200a of example embodiments may be formed by removing the edge blocks 230 and the outer side blocks 226 and 228 from the frequency variator 200 in FIG. 1.

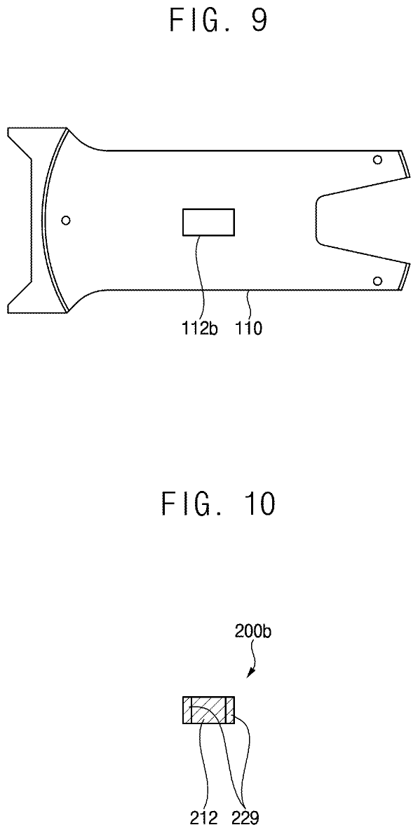

FIG. 8 is a plan view illustrating a robot blade in accordance with example embodiments, FIG. 9 is a plan view illustrating a blade body of the robot blade in FIG. 8 and FIG. 10 is a plan view illustrating a frequency variator of the robot blade in FIG. 8.

A robot blade 100b of example embodiments may include elements substantially the same as those of the robot blade 100 in FIG. 1 except for sizes of a frequency variation groove and a frequency variator. Thus, the same reference numerals may refer to the same elements and any further descriptions with respect to the same elements may be omitted herein for brevity.

Referring to FIGS. 8 to 10, a frequency variation groove 112b may be arranged at the central portion of the blade body 110. In example embodiments, the frequency variation groove 112b of example embodiments may have an area smaller than the area of the frequency variation groove 112a in FIG. 5. Thus, a frequency variator 200b selectively arranged in the frequency variation groove 112b may also have an area smaller than the area of the frequency variator 200a in FIG. 5.

For example, the frequency variator 200b may include only the first central block 212 and the auxiliary side blocks 229. That is, the frequency variator 200b of example embodiments may be formed by removing the second central blocks 214 and 216 and the inner side blocks 222 and 224 from the frequency variator 200a in FIG. 5.

FIG. 11 is a plan view illustrating a robot blade in accordance with example embodiments.

A robot blade 100c of example embodiments may include elements substantially the same as those of the robot blade 100a in FIG. 5 except for positions of a frequency variation groove and a frequency variator. Thus, the same reference numerals may refer to the same elements and any further descriptions with respect to the same elements may be omitted herein for brevity.

Referring to FIG. 11, a frequency variation groove 112c and a frequency variator 200c may be shifted left from the central portion of the blade body 110. For example, the frequency variation groove 112c and the frequency variator 200c may be offset from the central portion of the blade body 110. As used herein, “an element A is offset from an element B” (or similar language) may mean that the element A and the element B are not aligned along a vertical direction. The frequency variation groove 112 and the frequency variator 200 in FIG. 1 and the frequency variation groove 112b and the frequency variator 200b in FIG. 8 may also be shifted left from the central portion of the blade body 110 according to example embodiments.

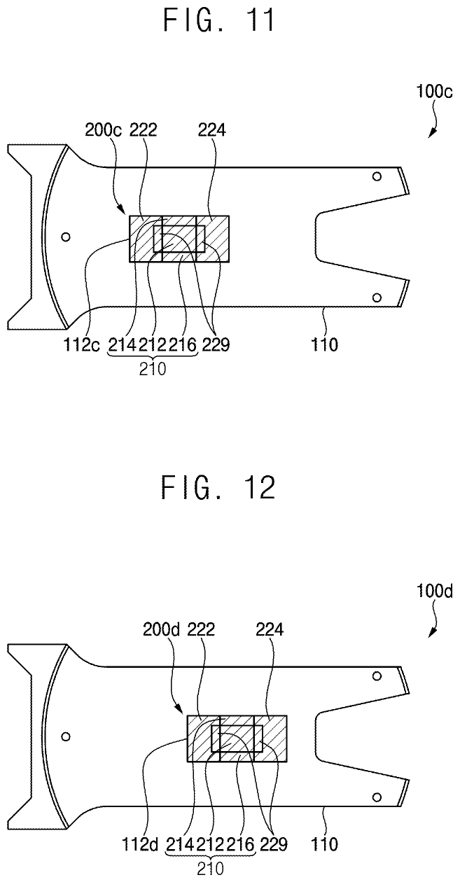

FIG. 12 is a plan view illustrating a robot blade in accordance with example embodiments.

A robot blade 100d of example embodiments may include elements substantially the same as those of the robot blade 100a in FIG. 5 except for positions of a frequency variation groove and a frequency variator. Thus, the same reference numerals may refer to the same elements and any further descriptions with respect to the same elements may be omitted herein for brevity.

Referring to FIG. 12, a frequency variation groove 112d and a frequency variator 200d may be shifted right from the central portion of the blade body 110. For example, the frequency variation groove 112d and the frequency variator 200d may be offset from the central portion of the blade body 110. The frequency variation groove 112 and the frequency variator 200 in FIG. 1 and the frequency variation groove 112b and the frequency variator 200b in FIG. 8 may also be shifted right from the central portion of the blade body 110 according to example embodiments.

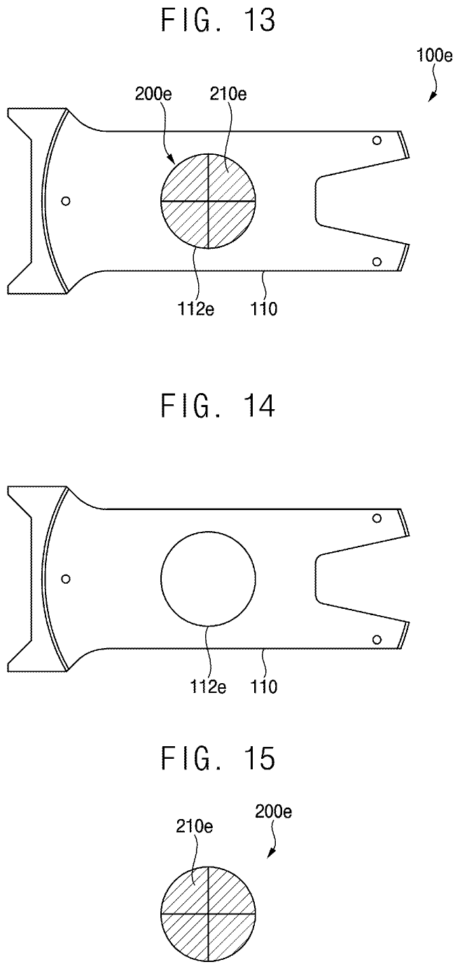

FIG. 13 is a plan view illustrating a robot blade in accordance with example embodiments, FIG. 14 is a plan view illustrating a blade body of the robot blade in FIG. 13 and FIG. 15 is a plan view illustrating a frequency variator of the robot blade in FIG. 13.

A robot blade 100e of example embodiments may include elements substantially the same as those of the robot blade 100 in FIG. 1 except for shapes of a frequency variation groove and a frequency variator. Thus, the same reference numerals may refer to the same elements and any further descriptions with respect to the same elements may be omitted herein for brevity.

Referring to FIGS. 13 to 15, a frequency variation groove 112e may have a circular shape. Thus, a frequency variator 200e may also have a circular shape corresponding to the circular shape of the frequency variation groove 112e

The frequency variator 200e may include four frequency variation blocks 210e. Each of the frequency variation blocks 210e may have about ¼ arc shape. For example, each of the frequency variation blocks 210e may have a quarter circle shape.

In example embodiments, the frequency variation groove and the frequency variator may have the rectangular shape or the circular shape, but are not limited thereto. For example, the frequency variation groove and the frequency variator may have a triangular shape, an elliptical shape, a trapezoidal shape, etc.

According to example embodiments, when the frequency of the blade body is coincided with a frequency of a part in semiconductor fabrication equipment, at least one of the frequency variation blocks may be removed from the frequency variation groove. Thus, the robot blade may have a changed shape by removing the at least one of the frequency variation blocks. Therefore, the robot blade having the changed shape may have a frequency different from the frequency of the part to prevent a resonance. As a result, a vibration of the robot blade may be suppressed to prevent damage to the semiconductor substrate.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A robot blade comprising:
a blade body that includes a frequency variation groove; and
a frequency variator configured to be detachably arranged in the frequency variation groove to vary a frequency of the blade body.

2. The robot blade of claim 1, wherein the frequency variation groove is at an upper surface of the blade body.

3. The robot blade of claim 2, wherein the frequency variation groove is positioned at a central portion of the upper surface of the blade body.

4. The robot blade of claim 2, wherein the frequency variation groove is offset from a central portion of the upper surface of the blade body.

5. The robot blade of claim 2, wherein the frequency variation groove has a rectangular shape.

6. The robot blade of claim 1, wherein the frequency variation groove has a uniform depth.

7. The robot blade of claim 1, wherein the frequency variator comprises a plurality of frequency variation blocks configured to be selectively arranged in the frequency variation groove.

8. The robot blade of claim 7, wherein the frequency variation blocks are configured to be arranged in a tessellation.

9. The robot blade of claim 8, wherein the frequency variation blocks collectively have an area substantially equal to an area of the frequency variation groove.

10. The robot blade of claim 8, wherein the frequency variation blocks comprise:
a central block configured to be arranged in a central portion of the frequency variation groove;
a plurality of side blocks having first side surfaces configured to contact first side surfaces of the central block, respectively; and
a pair of edge blocks configured to contact second side surfaces of the central block, respectively, and second side surfaces of the side blocks, respectively,
wherein the second side surfaces of the central block are substantially perpendicular to the first side surfaces of the central block, and the second side surfaces of the side blocks are substantially perpendicular to the first side surfaces of the side blocks.

11. The robot blade of claim 10, wherein the central block and the side blocks have rectangular shapes, and
wherein an area of the central block is substantially equal to an area of each of the side blocks.

12. The robot blade of claim 10, wherein the central block comprises:
a first central block configured to be arranged at the central portion of the frequency variation groove; and
a plurality of second central blocks configured to be arranged between opposing second side surfaces of the first central block and the edge blocks, respectively.

13. The robot blade of claim 12, wherein the side blocks comprise auxiliary side blocks configured to contact opposing first side surfaces of the first central block, respectively.

14. A robot blade comprising:
a blade body that includes a rectangular frequency variation groove at an upper surface of the blade body; and
a plurality of frequency variation blocks configured to be detachably arranged in the frequency variation groove to vary a frequency of the blade body.

15. The robot blade of claim 14, wherein the frequency variation groove is positioned at a central portion of the upper surface of the blade body.

16. The robot blade of claim 14, wherein the frequency variation groove is offset from a central portion of the upper surface of the blade body.

17. The robot blade of claim 14, wherein the frequency variation blocks are configured to be arranged in a tessellation.

18. The robot blade of claim 17, wherein the frequency variation blocks collectively have an area substantially equal to an area of the frequency variation groove.

19. A robot blade comprising:
a blade body that includes a rectangular frequency variation groove at an upper surface of the blade body; and
a plurality of frequency variation blocks configured to be detachably arranged in the frequency variation groove to vary a frequency of the blade body,
wherein the frequency variation blocks are configured to be arranged in a tessellation to collectively have an area substantially equal to an area of the frequency variation groove, and
wherein the frequency variation blocks comprise:
a central block configured to be arranged in a central portion of the frequency variation groove;
a plurality of side blocks having first side surfaces configured to contact first side surfaces of the central block, respectively; and
a pair of edge blocks configured to contact second side surfaces of the central block, respectively, and second side surfaces of the side blocks, respectively,
wherein the second side surfaces of the central block are substantially perpendicular to the first side surfaces of the central block, and the second side surfaces of the side blocks are substantially perpendicular to the first side surfaces of the side blocks.

20. The robot blade of claim 19, wherein the frequency variation groove is positioned at a central portion of the upper surface of the blade body.
